(19) United States
(12) Patent Application Publication
(10) Pub. No.: US 2007/0004144 A1
(43) Pub. Date: Jan. 4, 2007

(54) Method of fabricating dual gate oxide layer having different thickness in the cell region and the peripheral region

(76) Inventor: Jong Bum Park, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 11/302,812

(22) Filed: Dec. 14, 2005

(30) Foreign Application Priority Data
Jun. 30, 2005 (KR) 10-2005-0058087

(51) Int. Cl. H01L 21/336

(52) U.S. Cl. 438/258

(57) ABSTRACT

In fabricating a dual gate oxide layer, a first gate oxide layer is first formed on a semiconductor substrate, which has a cell region and a peripheral region. The first gate oxide layer is removed in the peripheral region. A second gate oxide layer is formed on the substrate using an atomic layer deposition method. A dual gate oxide layer having a stacked structure of the first and second gate oxide layers is formed in the cell region. A dual gate oxide layer having a stacked structure of a third gate oxide layer and the second gate layer is formed in the peripheral region. the dual gate oxide layer in the peripheral region is thinner than the dual gate oxide layer in the cell region.

### BACKGROUND OF THE INVENTION

1. Field of the invention

The present invention relates generally to a method of fabricating a semiconductor device, and more particularly to a method for fabricating a dual gate oxide layer, which can be applied when devices having different operational voltages are simultaneously formed in a single chip.

2. Description of the Prior Art

Generally, a transistor, e.g., a CMOS transistor, is fabricated using a process of forming dual gate oxide layer when two or more devices requiring different operational voltages are formed in a single semiconductor chip. That is, a thin gate oxide layer is applied to a peripheral region of the device needing high operating capability, while a thick gate oxide layer is applied to a cell region of the device which requires a high insulation resistant voltage characteristic.

A cell transistor requires higher threshold voltage than a transistor in the peripheral region due to problems in the refresh characteristics and others. Therefore, the cell transistors are subjected to high gate voltage during the device operations. For this reason, the gate oxide layer formed in the cell region must be thicker than the gate oxide layer formed in the peripheral region.

However, as an integration of a semiconductor device increase, it is required that the gate oxide layer in the cell region should attain an electric thickness below 25˜30 Å in order to secure desired capabilities of the cell transistor, (for example, to secure the operating current of the transistor and a suitable threshold voltage, and to reduce a short channel effect, etc.).

In the case of an conventional SiO2 gate oxide layer, its thickness must be physically reduced in order to reduce the electrical thickness of the gate oxide layer in the cell region, as described above. However, if the gate oxide layer made of SiO2 has the thickness less than 35 Å, leakage of current increases due to a direct tunneling. Further, there is a problem in that physical reduction of the thickness causes degradation in the reliability of the gate oxide layer.

That is, the gate capacitor in the cell region must secure a desired amount of electric charges. However, if the gate oxide layer becomes thin, the oxide layer losses its insulation characteristic so as to fail to act a role as a gate oxide layer.

### SUMMARY OF THE INVENTION

Accordingly, the present invention has been developed in order to solve the above-mentioned problems occurring in the prior art, and an object of the present invention is to provide a method for fabricating a dual gate oxide layer, in which a gate oxide layer is formed by using an insulation layer material of “SiO2 +high dielectric” instead of using only the SiO2 as in the prior art, so that the method can increase a physical thickness of the gate oxide layer in comparison with the conventional gate oxide layer while sufficiently reducing the electric thickness of the gate oxide layer, thereby reducing leakage of current caused by a direct tunneling and preventing the degradation of the reliability of a gate oxide layer.

In order to accomplish the object of the present invention, there is provided a method for fabricating a dual gate oxide layer, which comprises the steps of: forming a first gate oxide layer on a semiconductor substrate in which a cell region and a peripheral region are defined; removing the first gate oxide layer in the peripheral region; and forming a second gate oxide on the substrate using an atomic layer deposition method, wherein a gate oxide layer, having a stack structure in which the first and second gate oxide layers are stacked, is formed in the cell region, while a gate oxide layer having a stack structure in which a third gate oxide layer and the second gate layer are stacked is formed in the peripheral region, and the gate oxide layer in the peripheral region has a thickness smaller than that of the gate oxide layer in the cell region.

The first gate oxide layer is made of thermal oxide material, e.g. SiO2 or Oxynitride, and the second gate oxide layer is made of any one selected from AL2O3, HfO2, ZrO2 and Ta2O5. The third gate oxide layer is made of thermal oxide material, e.g. SiO2. Further, the first gate oxide layers respectively have a thickness less than 100Å. The first gate oxide layer is removed using buffered oxide etchant (BOE), or using Hydrogen Fluoride (HF) as etchant. Oxygen is supplied by using O3 or O2 plasma as the reaction gas during a formation of the second gate oxide layer.

If the dual gate is formed using the above mentioned method, the gate oxide layers in all the cell and peripheral regions has a structure of amorphous SiO2/Al2O3, thereby securing the gate oxide layer having higher dielectric constant than that of the conventional SiO2 and a film characteristic similar to SiO2. Therefore, even though the gate oxide layer in the cell region has a sufficient physical thickness, it is possible to significantly reduce the electric thickness of the gate oxide layer to a desired value.

### BRIEF DESCRIPTION OF THE DRAWINGS

The above and other objects, features, and advantages of the present invention will be more apparent from the following detailed description taken in conjunction with the accompanying drawings, in which:

FIGS. 1 to 4 are cross-sectional views for illustrating a method for fabricating dual gate oxide according to an embodiment of the present invention.

### DETAILED DESCRIPTION OF THE PREFERRED EMBODIMENTS

Hereinafter, preferred embodiments of the present invention will be described with reference to the accompanying drawings.

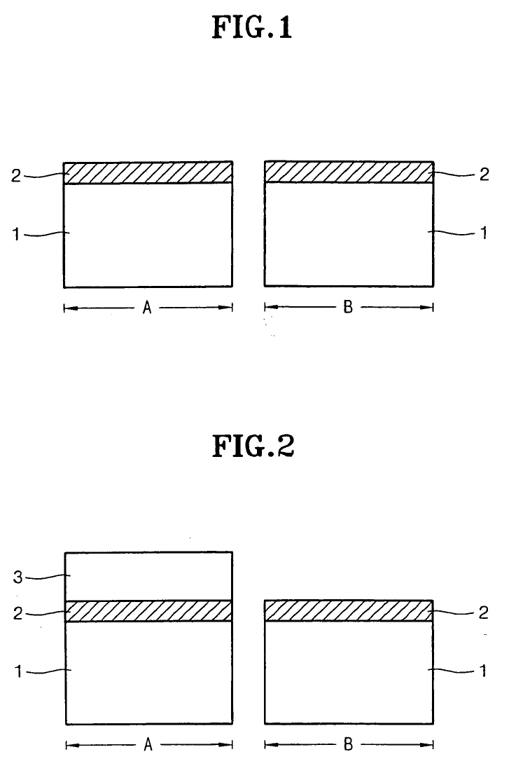

FIGS. 1 to 4 are cross-sectional views for illustrating a method of fabricating dual gate oxide layer according to an embodiment of the present invention. The method of fabricating a dual gate oxide layer will also be described in detail with reference to FIGS. 1 to 4.

As shown in FIG. 1, a first gate oxide layer 2 is formed on a semiconductor substrate 1, in which a cell region A and a peripheral region B are defined, so as to have a thickness less than 100 Å. At this time, the first gate oxide layer 2 is made of silicon oxide layer SiO2 or oxynitride layer by using thermal process.

As shown in FIG. 2, a photo-resist layer 3 is formed on the first gate oxide 2 in both regions A and B, and then the photo-resist layer 3 is patterned to expose the portion of the first gate oxide layer 2 in the peripheral region B.

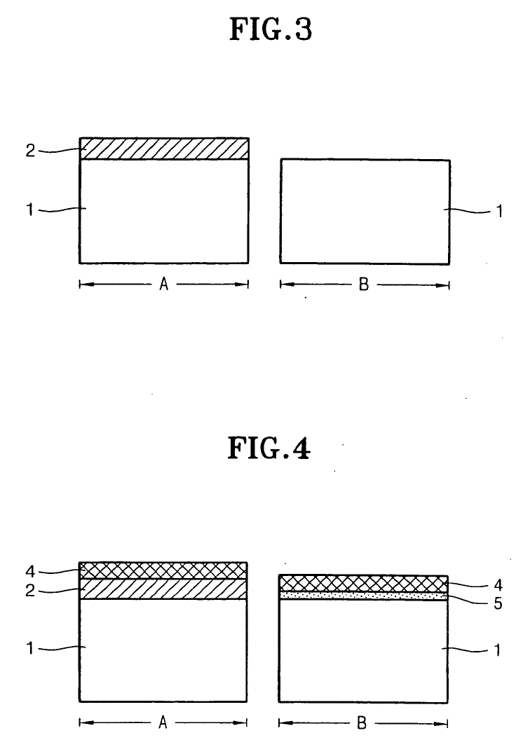

As shown in FIG. 3, the portion of the first gate oxide 2 formed in the peripheral region B is removed through an etch process using the photo-resist layer 3 remaining in the cell region A as an etch mask. At this time, the first gate oxide 2 is removed by a buffered oxide etchant (BOE) or a Hydrogen Fluoride (HF) etchant using a wet etching process. The photo-resist layer 3 in the cell region A used as the etch mask is removed through an etch process using the etchant of H2SO4+H2O2. As a result, the resultant of the substrate can be achieved in which the first gate oxide 2 remains on the substrate 1 in only the cell region A.

As shown in FIG. 4, a second gate oxide layer 4 of Al₂O₃ material is formed to a thickness less than 100 Å by an atomic layer deposition process under the pressure conditions of 0.1˜10Torr and at a temperature of 25˜500° C. The formation of the second gate oxide layer 4 of the Al₂O₃ material is achieved in four steps, which are below:

In a first step, tri methyl aluminum (Al(CH₃)₃) used as a source of aluminum flows down on the resultant substrate for 0.1˜10 seconds.

In a second step, nitrogen gas (N₂) flows down on the resultant substrate for 0.1˜10 seconds, in order to remove non-reacted source of the source forming an atomic layer.

In a third step, O₃ or O₂ plasma used as reaction gas flows down on the resultant substrate for 0.1˜10 seconds, so as to form oxygen atomic layer on the substrate.

In a fourth step, nitrogen gas (N₂) flows down on the resultant substrate for 0.1˜10 seconds, in order to remove non-reacted gas (O₃ or O₂ plasma).

The above first to fourth steps (achieving one cycle) are repeated until the second gate oxide layer 4 is formed to a desired thickness.

Simultaneously, a third gate oxide layer 5 of silicon dioxide having excellent oxide layer characteristics is formed below the second gate oxide layer 4 in the peripheral region B by the reaction gas, e.g. O₃ or O₂ plasma, used for depositing Al₂O₃ (see above step 3) in the peripheral region B of the substrate 1. The third gate oxide layer is formed by a reaction of silicon of the substrate and the reaction gas for the deposition of Al₂O₃.

Accordingly, the thick gate oxide layer (i.e., FIG. 4, elements 2, 4 in the region A) is formed in the cell region A, which has a stack structure comprising the second gate oxide layer 4 of Al₂O₃ material stacked on the first gate oxide layer 2 of SiO₂ material. The thin gate oxide layer (i.e., FIG. 4, elements 4, 5 in the region B) is formed in the peripheral region B, which has a stack structure comprising the second gate oxide layer 4 of Al₂O₃ material stacked on the third gate oxide layer 5 of SiO₂ material. That is, an amorphous “SiO₂/Al₂O₃” gate oxide layer is formed in both the cell and peripheral regions A and B but with different thickness.

As described above, when the gate oxide layer (such as 2, 4 in region A; or 4, 5 in region B) is formed in the “SiO₂/Al₂O₃” structure, it is possible to secure a higher dielectric constant than forming the gate oxide layer with the conventional SiO₂, while maintaining the film characteristics comparable to SiO₂. Thus, there is an advantage in that it can be applied to a next generation gate oxide layer.

Further, even though the gate oxide layer in the cell region A (such as FIG. 4, elements 2, 4) has the greater “physical” thickness, the “electrical” thickness of the gate oxide layer in the cell region A is sufficiently reduced to the desired extent (i.e., an electric thickness below 25˜30 Å), because the dielectric constant is higher than that of the conventional oxide layer (such as SiO2). Further, because the physical thickness of the gate oxide layer in the cell region A is sufficiently thick, the current leakage due to direct tunneling (which will occur if the physical thickness of the gate oxide layer in the cell region A is not sufficiently thick), and this resolves the problems associated with degradation in the reliability of the gate oxide layer.

As a variation of the above-embodiment of the present invention, the second gate oxide layer 4 may be made of an insulation substance (e.g. HfO2, ZrO2, Ta2O5, etc. having a high dielectric constant) instead of Al₂O₃, and likewise obtain all of the above-mentioned advantages.

Furthermore, the preferred embodiment of the present invention is described in the present disclosure in the context of fabricating a CMOS device; however, it should be understood that the present invention can also be applied in the fabrication of any complex chip, in which a memory device and a logic device are merged.

According to the embodiments of the present invention as described above, since the gate oxide layer is made of an insulation layer of “SiO₂ and another high dielectric material” instead of just SiO₂, it is possible to sufficiently reduce the electric thickness of the gate oxide layer to a desired extent, even though the physical thickness of the gate oxide layer in the cell region is increased. Accordingly, it is possible to prevent leakage of current and to improve the reliability of the gate oxide layer.

While a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A method of fabricating a dual gate oxide layer on a semiconductor substrate, the method comprising the steps of:
forming a first gate oxide layer on the semiconductor substrate, in which a cell region and a peripheral region are defined;
removing the first gate oxide layer in the peripheral region; and
forming a second gate oxide layer on the first gate oxide in the cell region and also forming a second gate oxide layer on the substrate in the peripheral region using an atomic layer deposition process,
wherein, during the atomic layer deposition process, a third gate oxide layer is also formed in the peripheral region between the second gate oxide layer and the semiconductor substrate,
wherein a cell region dual gate oxide layer comprising the second gate oxide layer stacked on the first gate oxide layer is formed in the cell region,
wherein a peripheral region dual gate oxide layer comprising the second gate oxide layer stacked on the third gate oxide layer is formed in the peripheral region, and
wherein the cell region dual gate oxide layer is physically thicker than the peripheral region dual gate oxide layer.

2. The method of fabricating a dual gate oxide layer as claimed in claim 1, wherein the first gate oxide layer is made of a thermal oxide material.

3. The method of fabricating a dual gate oxide layer as claimed in claim 2, wherein the thermal oxide material is a silicon oxide or a oxynitride.

4. The method of fabricating a dual gate oxide layer as claimed in claim 1, wherein the first gate oxide layer has a thickness less than 100 Å.

5. The method of fabricating a dual gate oxide layer as claimed in claim 1, wherein the first gate oxide layer in the peripheral region is removed by using a buffered oxide etchant (BOE) or by using Hydrogen Fluoride (HF) as an etchant.

6. The method of fabricating a dual gate oxide layer as claimed in claim 1, wherein the second gate oxide layer is made of any one material selected from AL₂O₃, HfO₂, ZrO₂, and Ta₂O₅.

7. The method of fabricating a dual gate oxide layer as claimed in claim 6, wherein the second gate oxide layer is formed to a thickness less than 100 Å by the atomic layer deposition process under the pressure conditions of 0.1˜10 Torr and at a temperature of 25˜500° C.

8. The method of fabricating a dual gate oxide layer as claimed in claim 7, wherein the formation of the second gate oxide layer of the Al₂O₃ material is achieved the following steps comprising:
i) flowing tri methyl aluminum Al(CH₃)₃ down on the cell region and the peripheral region of the substrate for 0.1˜10 seconds as a source of aluminum;
ii) after step i), flowing nitrogen gas N₂ down on the cell region and the peripheral region of the substrate for 0.1˜10 seconds;
iii) after step ii), flowing O₃ or O₂ plasma down on the cell region and the peripheral region of the substrate for 0.1˜10 seconds as a reaction gas;
iv) after step iii), flowing nitrogen gas N₂ down on the cell region and the peripheral region of the substrate for 0.1˜10 seconds, in order to remove non-reacted gas O₃ or O₂ plasma;
v) after step iv), repeating the steps i) to iv) until the second gate oxide layer is formed to a desired thickness.

9. The method of fabricating a dual gate oxide layer as claimed in claim 1, wherein the electric thickness of the cell region dual gate oxide layer is below 25˜30 Å.

10. The method of fabricating a dual gate oxide layer as claimed in claim 1, wherein the second gate oxide layer has a thickness of less than 100 Å.

11. The method of fabricating a dual gate oxide layer as claimed in claim 1, wherein oxygen is supplied by using O₃ or O₂ plasma as reaction gas when the second gate oxide layer is formed.

12. The method of fabricating a dual gate oxide layer as claimed in claim 1, wherein the third gate oxide layer is made of a thermal oxide material including silicon oxide.

13. The method of fabricating a dual gate oxide layer as claimed in claim 1, wherein the electric thickness of the cell region dual gate oxide layer is below 25˜30 Å.
